(19) United States
(12) Patent Application Publication
(10) Pub. No.: US 2017/0141348 A1
(43) Pub. Date: May 18, 2017

(54) OLED THIN FILM PACKAGING STRUCTURE, PACKAGING METHOD THEREOF AND DISPLAY DEVICE THEREOF

(71) Applicant: Shenzhen China Star Optoelectronics Technology Co., Ltd., Shenzhen, Guangdong (CN)

(72) Inventor: Wei YU, Shenzhen, Guangdong (CN)

(73) Assignee: Shenzhen China Star Optoelectronics Technology Co., Ltd., Shenzhen, Guangdong (CN)

(21) Appl. No.: 14/776,832

(22) PCT Filed: Jul. 17, 2015
(86) PCT No.: PCT/CN2015/084324

§ 371 Date: Sep. 15, 2015

(30) Foreign Application Priority Data
Jul. 1, 2015 (CN) 201510377349.1

(51) Int. Cl. H01L 51/52; H01L 51/56; H01L 51/00

(52) U.S. Cl. CPC H01L 51/5237; H01L 51/0097; H01L 51/56; H01L 2251/5338

(57) ABSTRACT

The disclosure provides an OLED thin film packaging structure, a packaging method thereof and a display device thereof. The packaging structure comprises: a base substrate; an OLED device, disposed on the base substrate; and a first passivation layer, covering the OLED device; wherein, a surface of the first passivation layer away from the OLED device comprises at least one thinning region, and the thickness of the thinning region is thinner than the thickness of the first passivation layer. Thus, the disclosure can enhance the bending property of the flexible OLED device packaging portion.

### TECHNICAL FIELD

The disclosure is related to the field of organic light-emitting diode, and more particularly to an OLED thin film packaging structure, a packaging method thereof and a display device thereof.

### RELATED ART

Organic light-emitting diode (OLED) is a new generation of displays. A organic thin film is manufactured on an OLED substrate, wherein the organic thin film is disposed between a cathode and an anode electrode. When a voltage is applied o the t o electrodes, the organic thin film emits light. OLED displays have many advantages, such as achieving flexbly displaying. A flexible OLED panel can be achieved by using a flexible plastic substrate as a substrate and then applying a thin film packaging process.

Presently, OLED thin film packaging apply a stacking structure of passivation layers ad buffering layers. In general, the passivation layer is made of inorganic materials, such as SiNx; the buffering layer is made of organic materials or partly organic materials.

The thin film packaging is micro-scale, and the inorganic film has a greater stress when the thickness is large, such that it is easily broken when being bent. Thus, moisture and oxygen would passing through the broken parts and aging the OLED device, such that the resistance to bending of the flexible OLED device packaging portion would be deteriorated.

### SUMMARY

The disclosure seeks to solve the problem of providing an OLED thin film packaging structure, a packaging method thereof and a display device thereof, so as to enhance the bending property of the flexible OLED device packaging portion.

In order to solve the above described technical problem, the disclosure provides a technical solution: providing an OLED device packaging structure. The packaging structure comprises: a base substrate; an OLED device, disposed on the base substrate; and a first passivation layer, covering the OLED device; wherein, a surface of the first passivation layer away from the OLED device comprises at least one thinning region, and the thickness of the thinning region is thinner than the thickness of the first passivation layer.

Wherein the thinning region comprises a plurality of banding regions interlacing with each other.

Wherein the thinning region comprises a plurality of rectangular regions disposed alternatively.

Wherein the packaging structure further comprises a second passivation layer covering the first passivation layer, a surface of the second passivation layer away from the OLED device comprises at least one thinning region, and the thickness of the thinning region is thinner than the thickness of the second passivation layer.

Wherein the thinning region of the first passivation layer and the thinning region of the second passivation layer are disposed alternatively.

Wherein the packaging structure further comprises a buffering layer, disposed between the first passivation layer and the second passivation layer, one surface of the buffering layer closed to the OLED device comprises at least one thickening region, configured for laminating with the thinning region of the first passivation layer.

In order to solve the above described technical problem, the disclosure provides another technical solution: providing a display device, the display device comprises an OLED device packaging structure. The packaging structure comprises: a base substrate; an OLED device, disposed on the base substrate; and a first passivation layer, covering the OLED device; wherein, a surface of the first passivation layer away from the OLED device comprises at least one thinning region, and the thickness of the thinning region is thinner than the thickness of the first passivation layer.

Wherein the thinning region comprises a plurality of banding regions interlacing with each other.

Wherein the thinning region comprises a plurality of rectangular regions disposed alternatively.

Wherein the packaging structure further comprises a second passivation layer covering the first passivation layer, a surface of the second passivation layer away from the OLED device comprises at least one thinning region, and the thickness of the thinning region is thinner than the thickness of the second passivation layer.

Wherein the thinning region of the first passivation layer and the thinning region of the second passivation layer are disposed alternatively.

Wherein the packaging structure further comprises a buffering layer, disposed between the first passivation layer and the second passivation layer, one surface of the buffering layer closed to the OLED device comprises at least one thickening region, configured for laminating with the thinning region of the first passivation layer.

In order to solve the above described technical problem, the disclosure provides another technical solution: providing a method for packaging an OLED device, the packaging method comprises: providing a base substrate; forming an OLED device on the base substrate; forming first passivation layer covering the OLED device; and forming at least one thinning region on the first passivation layer, and the thickness of the thinning region is thinner than a normal thickness of the first passivation layer.

Wherein after the step of forming at least one thinning region on the first passivation layer, and the thickness of the thinning region is thinner than a normal thickness of the first passivation layer, the method further comprises: forming a buffering layer on the first passivation layer; forming a second passivation layer on the buffering layer; and forming at least one thinning region on the second passivation layer, and the thickness of the thinning region is thinner than a normal thickness of the second passivation layer.

Wherein the thinning region of the first passivation layer and the thinning region of the second passivation layer are disposed alternatively.

The advantageous effect of the disclosure: as compared with the present technology, the packaging structure disclosed by the disclosure comprises: a base substrate, an OLED device disposed on the base substrate, and a first passivation layer covering the OLED device; wherein, a surface of the first passivation layer away from the OLED device comprises at least one thinning region, and the thickness of the thinning region is thinner than the thickness of the first passivation layer. Thus, when the packaging structure is bent, the first passivation layer would not be broken because of its stress, such that the disclosure can ensure that the resistance of the flexible OLED to bending is better.

### BRIEF DESCRIPTION OF THE DRAWINGS

In order to more clearly illustrate the embodiments of the disclosure, the accompanying drawings for illustrating the technical solutions and the technical solutions of the disclosure are briefly described as below.

FIG. 1 is a schematic view of the OLED device packaging structure according to the first embodiment the disclosure;

FIG. 2 is a schematic view of the OLED device packaging structure according to the second embodiment the disclosure;

FIG. 3 is a top view of the first passivation layer of the OLED device packaging structure according to the second embodiment the disclosure;

FIG. 4 is a top view of the second passivation layer of the OLED device packaging structure according to the second embodiment the disclosure;

FIG. 5 is a schematic view of the mask during the process of manufacturing the first passivation layer of the OLED device packaging structure according to the second embodiment the disclosure;

FIG. 6 is a schematic view of the semi hollow region of the mask during the process of manufacturing the first passivation layer of the OLED device packaging structure according to the second embodiment the disclosure;

FIG. 7 is another top view of the first passivation layer of the OLED device packaging structure according to the second embodiment the disclosure;

FIG. 8 is a flow chart of the OLED device packaging method according to the first embodiment of the disclosure;

FIG. 9 is a flow chart of the OLED device packaging method according to the second embodiment of the disclosure; and

FIG. 10 is a schematic view of the display device according to an embodiment of the disclosure.

### DETAILED DESCRIPTION

The following description with reference to the accompanying drawings is provided to clearly and completely explain the exemplary embodiments of the disclosure. It is apparent that the following embodiments are merely some embodiments of the disclosure rather than all embodiments of the disclosure. According to the embodiments in the disclosure, all the other embodiments attainable by those skilled in the art without creative endeavor belong to the protection scope of the disclosure.

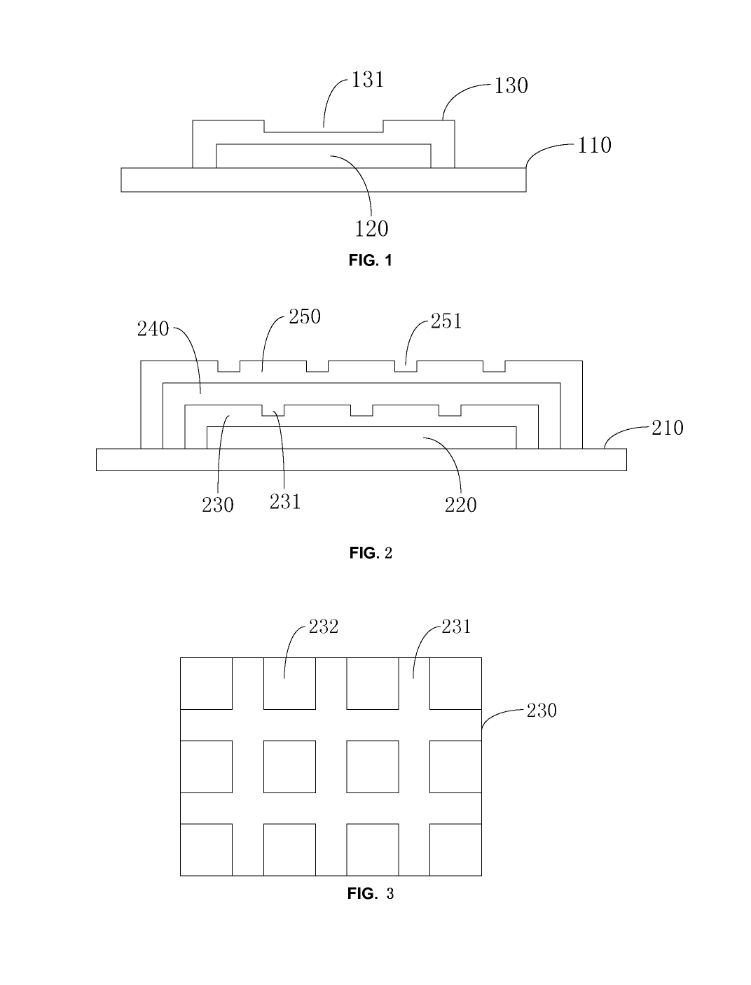

Referring to FIG. 1, which a schematic view of the OLED device packaging structure according to the first embodiment the disclosure. The packaging structure comprises: a base substrate 110; an OLED device 120, disposed on the base substrate 110; and a first passivation layer 130, covering the OLED device 120; wherein, a surface of the first passivation layer 130 away from the OLED device 120 comprises at least one thinning region 131, and the thickness of the thinning region 131 is thinner than the thickness of the first passivation layer 130.

Wherein, the base substrate 110 is generally a glass substrate. When manufacturing flexible panels, plastic substrates, which are bendable, can be used.

The OLED device 120 comprises an anode, a cathode and electroluminescent materials disposed between the anode and cathode. When an electrical circuit is applied to the anode and cathode, the electroluminescent materials emit light.

The first passivation layer 130 is generally made of inorganic materials, such as metal oxides, metal sulfides, metal nitrides and so forth. For example, the metal oxides comprise calcium oxide, tantalum pentoxide, titanium dioxide, zirconium dioxide, copper oxide, zinc oxide, aluminum oxide, chromium oxide, tin oxide, nickel oxide, and antimony pentoxide; the metal sulfides comprise titanium disulfide, iron sulfide, chromium trisulphide, copper sulfide, zinc sulfide, tin sulfide, nickel sulfide, cobalt trisulfide, antimony trisulfide, lead sulfide, lanthanum trisulfide, cerium sulfide, zirconium disulfide and so forth; the metal nitrides comprise silicon nitride, aluminum nitride and so forth.

The first passivation layer 130 can be formed by vacuum deposition, ion beam sputtering, magnetron sputteringdeposition, chemical vapor deposition, atomic layer deposition and so forth. During the process, the angle between the incident particles and the normal line of the base substrate can be determined according to actual conditions. When the angle is 0°, the surface of the first passivation layer 130 is smooth and the arrangement is dense.

The thinning regions 131 can be formed by process of lithography and etching on the top surface of the first passivation layer 130. Alternatively, the thinning regions 131 can be formed by a modified mask, such that the thinning regions 131 is formed by an extra thin passivation layer during the process of forming the first passivation layer 130.

Certainly, the shape and the quantity of the thinning region 131 is not limited by FIG. 1. The quantity of the thinning region 131 can be increased, and the shape of the thinning region 131 can be changed; in addition, the quantity of the thinning region and the buffering layer is not limited to the quantity of the embodiment, and one can increase the quantity of the thinning region and the buffering layer according to their needs.

Since part of the thinning region 131 is disposed on the first passivation layer 130, such that the edge section would not be squeezed. Thus, when the whole packaging structure is bent, the first passivation layer would not be broken because that its stress is too large.

As compared with the present technology, the packaging structure disclosed by the disclosure comprises: a base substrate, an OLED device disposed on the base substrate, and a first passivation layer covering the OLED device; wherein, a surface of the first passivation layer away from the OLED device comprises at least one thinning region, and the thickness of the thinning region is thinner than the thickness of the first passivation layer. Thus, when the packaging structure is bent, the first passivation layer would not be broken because that its stress is greater, such that the disclosure can ensure the resistance to bending of the flexible OLED.

Referring to FIG. 2, which is a schematic view of the OLED device packaging structure according to the second embodiment the disclosure. The packaging structure comprises: a base substrate 210; an OLED device 220, disposed on the base substrate 210; a first passivation layer 230, covering the OLED device 220; a buffering layer 240, covering the first passivation layer 230; and a second passivation layer 250 covering the buffering layer 240.

Wherein, a surface of the first passivation layer 230 away from the OLED device 220 comprises at least one thinning region 231, and the thickness of the thinning region 231 is thinner than the thickness of the first passivation layer 230; a surface of the second passivation layer 250 away from the OLED device 220 comprises at least one thinning region 251, and the thickness of the thinning region 251 is thinner than the thickness of the second passivation layer 250.

Wherein, the buffering layer 240 is generally made of organic material, such as polyethylene terephthalate (PET), polyethylene naphthalate (PEN), polycarbonate (PC), polyimide (PI), polyvinyl chloride (PVC), polystyrene (PS), polymethyl methacrylate (PMMA), poly (butylene terephthalate) (PBT), polysulfone (PSO), polyethylene terephthalate ethyl sulfone (PES), polyethylene (PE), polypropylene (PP), polysiloxane (Silicone), polyamide (PA), polyvinylidene fluoride (PVDF), ethylene-vinyl acetate copolymer (EVA), ethylene-vinyl alcohol copolymer (EVAL), poly acrylonitrile (PAN), polyvinyl acetate (PVAC), parylene, polyurea or polytetrafluoroethylene (PTFE), epoxy resin and so forth.

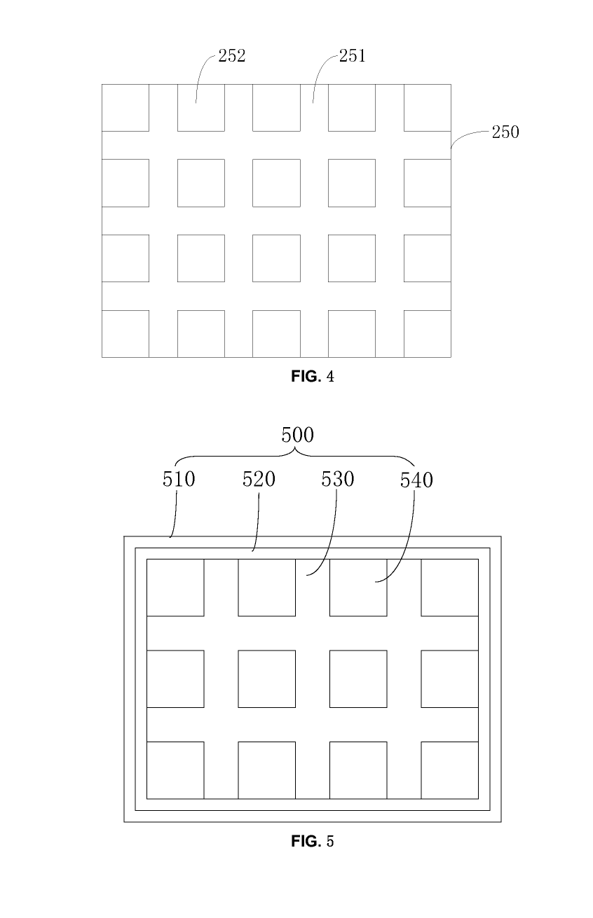

Referring to FIGS. 3 and 4, the thinning region 231 of the first passivation layer 230 comprises a plurality of banding regions interlacing with each other, and other regions are named as normal regions 232; meanwhile, the thinning region 251 of the second passivation layer 250 comprises a plurality of banding regions interlacing with each other, and other regions are named as normal regions 252.

When manufacturing the first passivation layer 230, a mask 500 as shown in FIG. 5 can be used. The mask 500 comprises a frame 510, a non hollow region 520, a semi hollow region 530 and a hollow region 540. When applying the mask 500 for coating, the regions corresponding to the frame 510 and the non hollow region 520 does not form films, the region corresponding to the semi hollow region 530 forms the thinning region 231, and the region corresponding to the hollow region 540 forms the normal region 232.

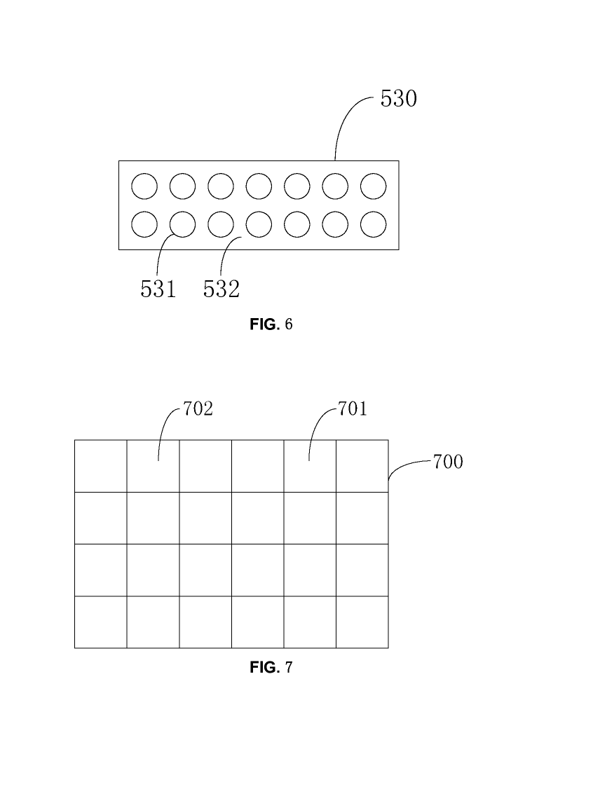

As shown in FIG. 6, the semi hollow region 530 comprises a hole region 531 and a non hole region 532, such that only coating materials can pass through the hole region 531, and the materials can pass through the whole hollow region 540, such that the thinning region 231 formed corresponding to the semi hollow region 530 is thinner than the normal region 232 formed corresponding to the hollow region 540.

The manufacture of the second passivation layer 250 is similar, so that the disclosure does not describe it again.

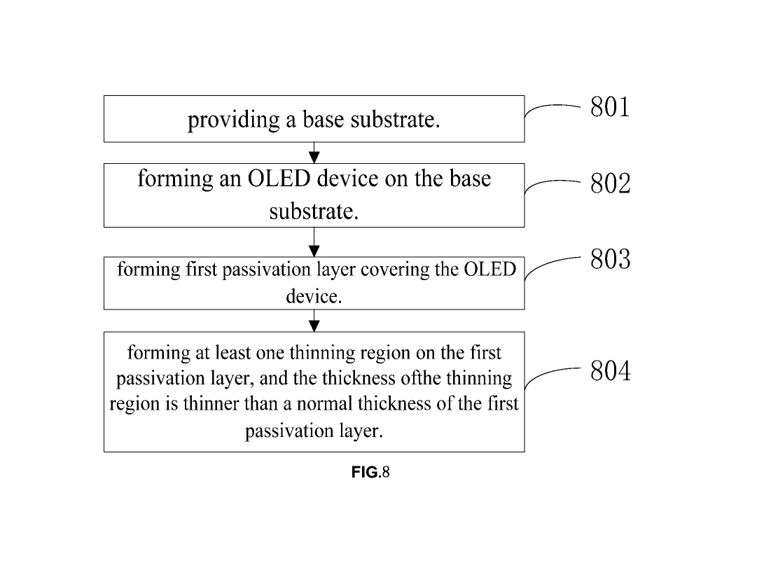

In addition, the thinning regions and the normal regions of the first passivation layer 230 and the second passivation layer 230 can have different shapes. As shown in FIG. 7, the thinning region 701 of the first passivation layer 700 can be a plurality of rectangular regions disposed alternatively. Certainly, the shape of the mask can be adjusted according to the shape of the thinning region 701.

Referring to FIGS. 2 to 4, in one embodiment, the thinning region 231 of the first passivation layer 230 and the thinning region 251 of the second passivation layer 250 are disposed alternatively. In other words, the thinning region 231 of the first passivation layer 230 corresponds to the normal region 252 of the second passivation layer 250, and the thinning region 251 of the second passivation layer 250 corresponds to the normal region 232 of the first passivation layer 230.

As compared with the present technology, in the disclosure, the first passivation layer, the buffering layer and the second passivation layer are covered on the OLED device in sequence, as well as the thinning region of the first passivation layer and the thinning region of the second passivation layer are disposed alternatively, such that the number of thinning regions of the packaging structure is increased. Considering more bending points, the disclosure can ensure that the resistance of the flexible OLED to bending is better, such that when the packaging structure is bent, the passivation layer(s) would not be broken because that its (their) stress is greater.

Referring to FIG. 8, which is a flow chart of the OLED device packaging method according to the first embodiment of the disclosure, and the method comprises:

Step 801: providing a base substrate;

Step 802: forming an OLED device on the base substrate;

Step 803: forming first passivation layer covering the OLED device; and

Step 804: forming at least one thinning region on the first passivation layer, and the thickness of the thinning region is thinner than a normal thickness of the first passivation layer.

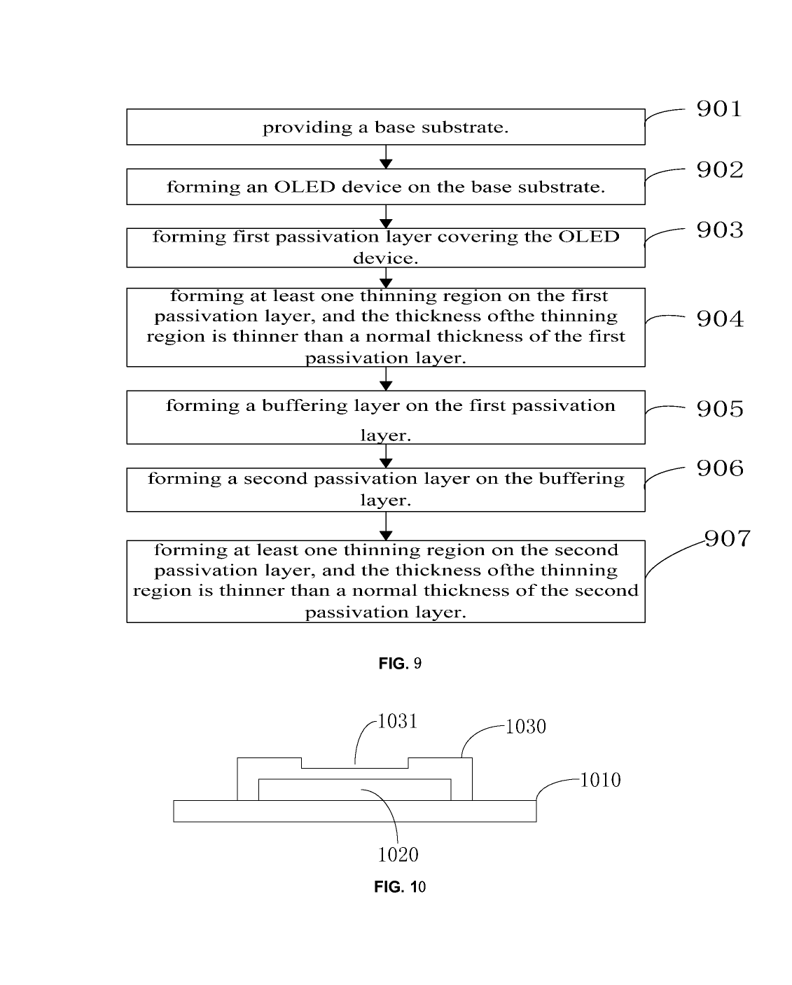

Referring to FIG. 9, which is a flow chart of the OLED device packaging method according to the second embodiment of the disclosure, and the method comprises:

Step 901: providing a base substrate;

Step 902: forming an OLED device on the base substrate;

Step 903: forming first passivation layer covering the OLED device;

Step 904: forming at least one thinning region on the first passivation layer, and the thickness of the thinning region is thinner than a normal thickness of the first passivation layer;

Step 905: forming a buffering layer on the first passivation layer;

Step 906: forming a second passivation layer on the buffering layer; and

Step 907: forming at least one thinning region on the second passivation layer, and the thickness of the thinning region is thinner than a normal thickness of the second passivation layer.

Wherein, the thinning region of the first passivation layer and the thinning region of the second passivation layer are disposed alternatively.

The above described method is based on one embodiment of the OLED device packaging structure of the disclosure, and the technical principles are similar, such that the disclosure does not describe them again.

Referring to FIG. 10, which is a schematic view of the display device according to an embodiment of the disclosure. The display device comprises the OLED packaging structure, which is described in the above embodiments, i.e. a base substrate 1010; an OLED device 1020 disposed on the base substrate 1010; and a first passivation layer 1030, covering the OLED device 1020; wherein, a surface of the first passivation layer 1030 away from the OLED device 1020 comprises at least one thinning region 1031, and the thickness of the thinning region 1031 is thinner than the thickness of the first passivation layer 1030. Wherein, the OLED device 1010 comprises an organic thin film, and the organic thin film is disposed between a cathode and an anode metal. When a voltage is applied to the two electrodes, the organic thin film emits light.

Note that the specifications relating to the above embodiments should be construed as exemplary rather than as limitative of the present disclosure. The equivalent variations and modifications on the structures or the process by reference to the specification and the drawings of the disclosure, or application to the other relevant technology fields directly or indirectly should be construed similarly as falling within the protection scope of the disclosure.

What is claimed is:

1. An OLED device packaging structure, wherein the packaging structure comprises:
a base substrate;
an OLED device, disposed on the base substrate; and
a first passivation layer, covering the OLED device;
wherein, a surface of the first passivation layer away from the OLED device comprises at least one thinning region, and the thickness of the thinning region is thinner than the thickness of the first passivation layer.

2. The packaging structure according to claim 1, wherein the thinning region comprises a plurality of banding regions interlacing with each other.

3. The packaging structure according to claim 1, wherein the thinning region comprises a plurality of rectangular regions disposed alternatively.

4. The packaging structure according to claim 1, wherein the packaging structure further comprises a second passivation layer covering the first passivation layer, a surface of the second passivation layer away from the OLED device comprises at least one thinning region, and the thickness of the thinning region is thinner than the thickness of the second passivation layer.

5. The packaging structure according to claim 4, wherein the thinning region of the first passivation layer and the thinning region of the second passivation layer are disposed alternatively.

6. The packaging structure according to claim 4, wherein the packaging structure further comprises a buffering layer, disposed between the first passivation layer and the second passivation layer, one surface of the buffering layer closed to the OLED device comprises at least one thickening region, configured for laminating with the thinning region of the first passivation layer.

7. A display device, wherein the display device comprises an OLED device packaging structure, the packaging structure comprises:
a base substrate;
an OLED device, disposed on the base substrate; and
a first passivation layer, covering the OLED device;
wherein, a surface of the first passivation layer away from the OLED device comprises at least one thinning region, and the thickness of the thinning region is thinner than the thickness of the first passivation layer.

8. The display device according to claim 7, wherein the thinning region comprises a plurality of banding regions interlacing with each other.

9. The display device according to claim 7, wherein the thinning region comprises a plurality of rectangular regions disposed alternatively.

10. The display device according to claim 7, wherein the packaging structure further comprises a second passivation layer covering the first passivation layer, a surface of the second passivation layer away from the OLED device comprises at least one thinning region, and the thickness of the thinning region is thinner than the thickness of the second passivation layer.

11. The display device according to claim 10, wherein the thinning region of the first passivation layer and the thinning region of the second passivation layer are disposed alternatively.

12. The display device according to claim 10, wherein the packaging structure further comprises a buffering layer, disposed between the first passivation layer and the second passivation layer, one surface of the buffering layer closed to the OLED device comprises at least one thickening region, configured for laminating with the thinning region of the first passivation layer.

13. A method for packaging an OLED device, wherein thepackaging method comprises:
providing abase substrate;
forming an OLED device on the base substrate;
forming first passivation layer covering the OLED device; and
forming at least one thinning region on the first passivation layer, and the thickness of the thinning region is thinner than a normal thickness of the first passivation layer.

14. The method according to claim 13, wherein after the step of forming at least one thinning region on the first passivation layer, and the thickness of the thinning region is thinner than a normal thickness of the first passivation layer, the method further comprises:
forming a buffering layer on the first passivation layer;
forming a second passivation layer on the buffering layer; and
forming at least one thinning region on the second passivation layer, and the thickness of the thinning region is thinner than a normal thickness of the second passivation layer.

15. The method according to claim 14, wherein the thinning region of the first passivation layer and the thinning region of the second passivation layer are disposed alternatively.
